(19) United States
(12) Patent Application Publication
(10) Pub. No.: US 2003/0181051 A1
(43) Pub. Date: Sep. 25, 2003

(54) Method of fabricating a flash memory cell

(76) Inventors: Kent Kuohua Chang, Taipei City (TW); Weng-Hsing Huang, Hsin-Chu City (TW)

Correspondence Address: NAIPO (NORTH AMERICA INTERNATIONAL PATENT OFFICE), P.O. BOX 506, MERRIFIELD, VA, 22116, US

(21) Appl. No.: 10/063,134

(22) Filed: Mar. 25, 2002

(51) Int. Cl. H01L 21/311

(52) U.S. Cl. 438/694

(57) ABSTRACT

A simplified flash memory fabrication process is disclosed. The method includes the following steps: 1) forming a stacked layer on a substrate in the channel region, and the stacked layer is a polysilicon layer and a sacrificial layer formed atop the polysilicon layer; 2) depositing a dielectric layer to cover the channel region and the bit line region; 3) performing an isotropic dry etching process to etch away a predetermined thickness of the dielectric layer to expose a portion of the sacrificial layer, and at the same time, dividing the dielectric layer into a first portion dielectric layer positioned atop the sacrificial layer and a second portion dielectric layer that is not connected with the first portion dielectric layer; and 4) completely removing the sacrificial layer and the first portion dielectric layer.

### BACKGROUND OF THE INVENTION

1. Field of the Invention

The present invention relates to a method of forming a high-GCR (gate coupling ratio) flash memory, and more particularly, to a high-GCR and high reliability flash memory fabrication method utilizing an isotropic dry etching process to simplify the flash memory making process, and eliminate HF acid corrosion during the fabrication processes and reduce random bit failures.

2. Background of the Invention

For the past few years, there has been an increasing demand for portable electronic products, such as film for digital cameras, mobile phones, video game consoles, personal digital assistants(PDAs), MP3 players, etc. This has driven the development of flash memory fabrication technology. Due to its highly reduced weight and physical dimensions compared to magnetic memories such as hard disk or floppy disk memories, flash memory has a tremendous potential in the consumer electronics market.

Flash memories are high-density non-volatile semiconductor memories offering fast access times. The flash memories can store data in the memory under an electrical power off state, and read/write data through controlling a threshold voltage of a control gate. Typically, The flash memory is designed as a stacked-gate structure. In a stacked-gate flash memory operation, the stacked-gate electrode comprises a control gate and one or more floating gates separated by a thin dielectric layer. When the control gate is charged, hot electrons will travel across the gate oxide layer and cause the floating gate to be charged. After the power is turned off, the oxide layer surrounding the floating gate prevents the charge from dissipated. The data stored in the memory is renewed/erased through applying extra energy to the stacked-gate flash memory cell. The control gate to floating gate coupling ratio or the gate coupling ratio (GCR), that is related to the area overlap between control gate and the floating gate, affects the read/write speed of the flash memory.

Please refer to FIG. 1 to FIG. 4. FIG. 1 to FIG. 4 are cross-sectional diagrams of forming a dual-bit stacked-gate flash memory cell according to the prior art. As shown in FIG. 1, the semiconductor wafer 10 comprises a silicon substrate 12, an active area 11 isolated by a field oxide layer 14 positioned on the silicon substrate 12, two gate structure 21 positioned within the active area 11 on the silicon substrate 12. Each gate structure 21 comprises a gate oxide layer 16 formed on the silicon substrate 12, a polysilicon layer (hereinafter referred to as PL1 layer) 18 positioned on the gate oxide layer 16, and a silicon nitride layer 20 positioned on the PL1 layer 18.

According to the prior art, as shown in FIG. 2, an ion implantation process is performed to implant ions into the surface of the silicon substrate 12 that is not covered by the gate structure 21, i.e. into a bit line region. A thermal oxidation process is then performed to activate the doped ions to form a diffusion region 22 serving as a buried drain or source (BD/BS) or a bit line, followed by a thermal oxide layer or BD/BS oxide layer 24 grown over the diffusion region 22. As shown in FIG. 3, the silicon nitride layer 20 is then removed and a polysilicon layer 26 are formed over each PL1 layer 18. The PL1 layer 18 and the polysilicon layer 26 form a floating gate 28.

As shown in FIG. 4, a dielectric layer 30 is formed on the surface of the floating gate 28 and a polysilicon layer 32 is then formed serving as a control gate of the stacked-gate flash memory cell. Typically, the dielectric layer 30 is an ONO structure that comprises a bottom oxide layer, a nitride layer positioned on the bottom oxide layer and a top oxide layer positioned on the nitride layer.

The drawbacks of the prior art method of making a flash memory cell include: 1) since the BD/BS oxide layer 24 is formed by a thermal oxidation method, the thickness of the BD/BS oxide layer 24 is not uniform for wafer-to-wafer aspect or die-to-die aspect, thus causing a reliability problem; 2) due to bird's beak effects created by the prior art thermally formed BD/BS oxide layer 24, the lattice structure of the substrate 12 is damaged, and the reliability of the stacked-gate flash memory is hence dramatically reduced; 3) the formation of the BD/BS oxide layer 24 overly diffuses ions into the drain and source resulting in a shortened channel length. This causes an occurrence of a punch through between the source and the drain, influencing the electrical performance of the stacked-gate flash memory; 4) insufficient gate coupling ratio (GCR).

### SUMMARY OF INVENTION

It is therefore a primary objective of the present invention to provide a simplified method of fabricating a high GCR stacked-gate non-volatile memory with improved reliability.

It is another objective of the present invention to precisely control the channel length of the stacked-gate flash memory and the thickness of the BD/BS oxide layer.

It is still another objective of the present invention to reduce the random bit failures caused by acid penetration with an anisotropic etching process during the fabrication of the flash memory.

According to the preferred embodiment of the present invention, the method comprises the following steps: (1) providing a substrate, that comprises a channel region and a bit line region in its surface; (2) forming a stacked layer on the substrate in the channel region, wherein the stacked layer comprises a polysilicon layer and a sacrificial layer formed on the polysilicon layer; (3) depositing a dielectric layer to cover the channel region and the bit line region, the top surface of the dielectric layer on the surface of the substrate is above the top surface of the polysilicon layer and below the top surface of the sacrificial layer; (4) performing an isotropic dry etching process to etch away a predetermined thickness of the dielectric layer to expose a portion of the sacrificial layer, and at the same time, divide the dielectric layer into a first portion dielectric layer positioned on the sacrificial layer and a second portion dielectric layer that is not connected with the first portion dielectric layer; and (5) completely removing the sacrificial layer and the first portion dielectric layer.

It is an advantage of the present invention that not only the channel length of the stacked-gate flash memory and the thickness of the dielectric layer (used as a BD/BS oxide layer) are precisely controlled, but also the size of the devices, to improve the reliability of the devices, effectively shrink. A 60 to 75% gate coupling ratio gain of the stacked-gate flash memory is achieved. Additionally, the isotropic dry etching process prevents acid penetration and acid-corroded seams forming during the acid solution dipping process in the prior art method, thereby reducing random bit failures.

These and other objectives of the present invention will no doubt become obvious to those of ordinary skill in the art after having read the following detailed description of the preferred embodiment that is illustrated in the various figures and drawings.

### BRIEF DESCRIPTION OF DRAWINGS

FIG. 1 to FIG. 4 are cross-sectional diagrams of forming a stacked-gate flash memory according to the prior art method; and FIG. 5 to FIG. 11 are cross-sectional diagrams of forming a high-GCR flash memory according to the present invention.

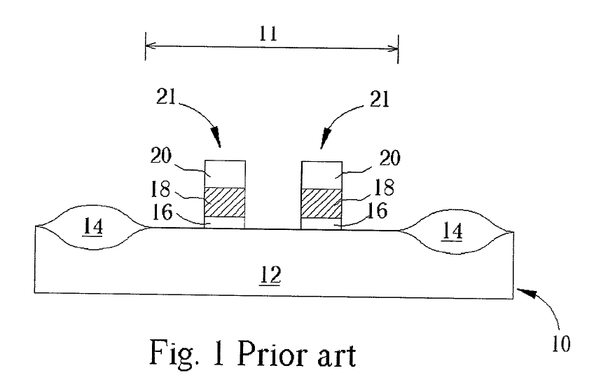

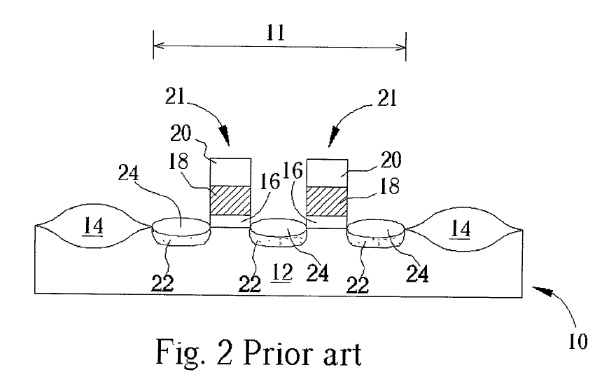

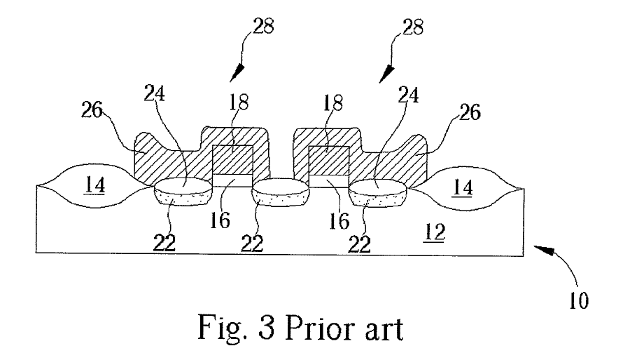

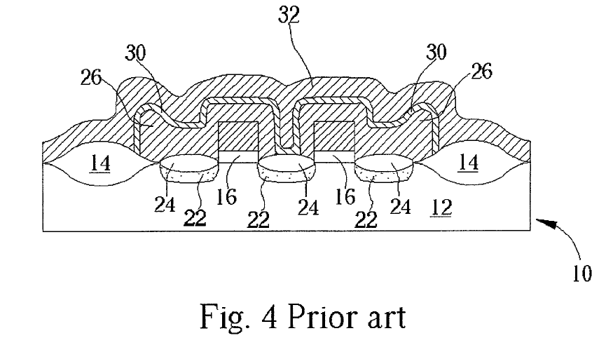

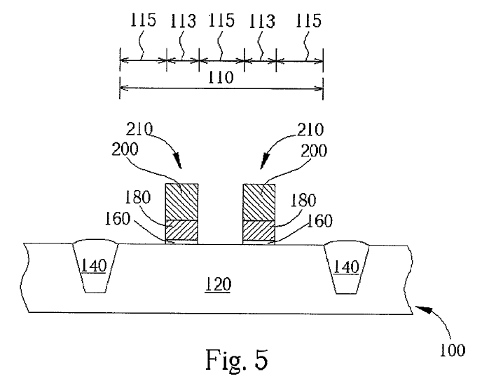

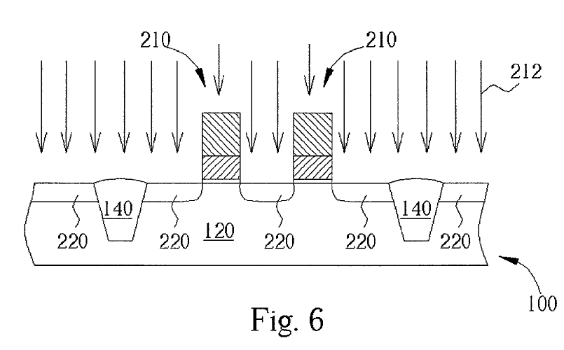

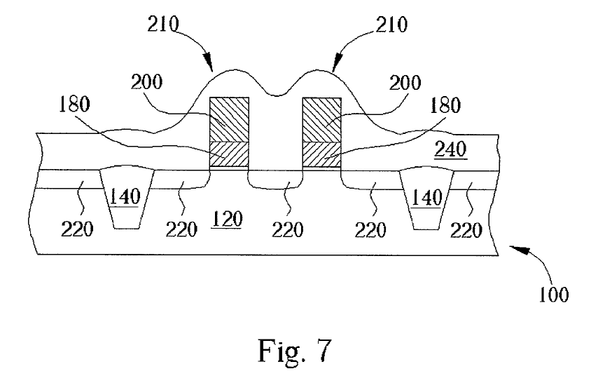

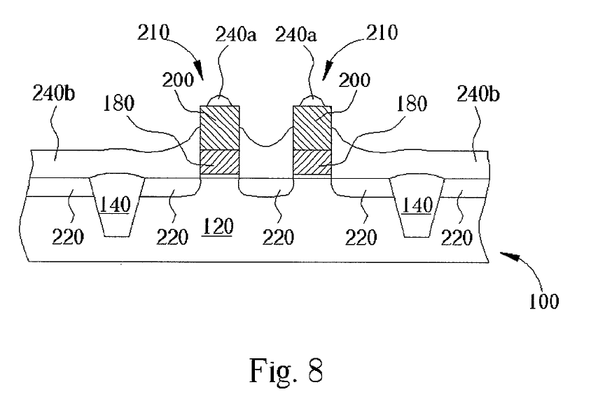

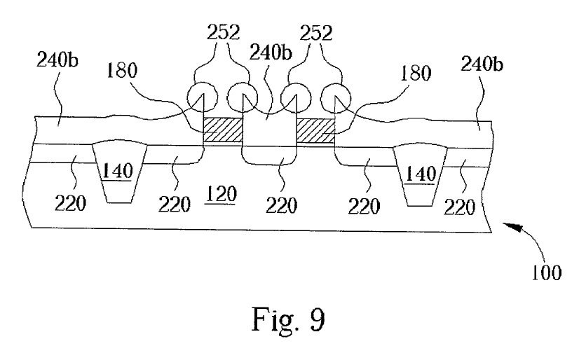

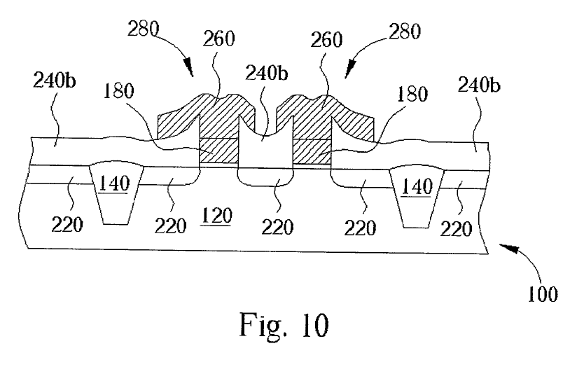

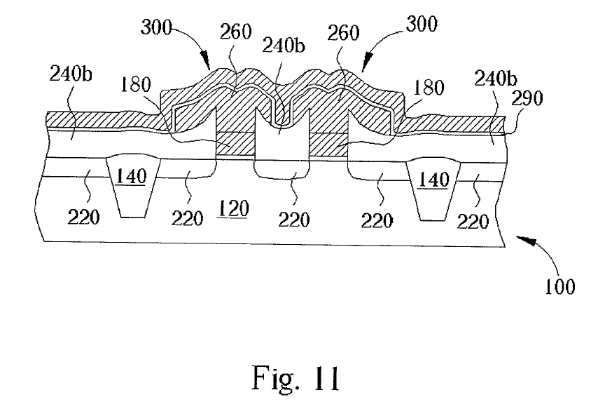

### DETAILED DESCRIPTION

The simplified high-GCR flash memory process according to the preferred embodiment of the present invention will now be described in detail.

Please refer to FIG. 5 to FIG. 11. FIG. 5 to FIG. 11 are schematic diagrams showing of a preferred method of fabricating a high-GCR flash memory according to the present invention. As shown in FIG. 5, a semiconductor wafer 100 comprising a silicon substrate 120 is first provided. An active area 100 isolated by a shallow trench isolation region 140 is positioned on the silicon substrate 120. Two gate structures 210 are formed within the active area 110. Each gate structure 210 comprises a tunnel oxide layer 160 formed on the silicon substrate 120, a PL1 layer 180, composed of polysilicon, positioned on the gate oxide layer 160, and a silicon nitride sacrificial layer 200 positioned on the PL1 layer 180. After the formation of the gate structures 210, the active area 10 is further divided into a channel region 113 and a bit line region 115.

In the preferred embodiment of the present invention, the silicon substrate 120 is a P-type single crystal silicon substrate with a <100> crystalline orientation. Alternatively, the semiconductor substrate may be a silicon-on-insulator (SOI) substrate, an epitaxy silicon substrate, or any other silicon substrate of various lattice structures. Preferably, the tunnel oxide layer 160 has a thickness of about 90 to 120 angstorms, more preferably 95 angstroms. The PL1 layer 180 has a thickness of about 1000 angstroms. The sacrificial layer 200 has a thickness from 1200 to 1600 angstroms, preferably 1400 angstroms. The sacrificial layer 200 may be formed by a chemical vapor deposition (CVD) method, such as a low pressure CVD method, in a SiH₂ Cl₂/NH₃ system, at a temperature of about 750° C. The PL1 layer 180 is deposited in a SiH ₄ medium at a temperature of about 620° C. Generally, the after-etch-inspect critical dimension (AEICD) of the PL1 layer 180, i.e. floating gate channel length, is about 0.34 microns.

As shown in FIG. 6, an ion implantation process 212 using arsenic (As) as an ion source is performed to implant As into the bit line region 115 of the silicon substrate 120 that is not covered by the gate structure 210, so as to form a doped region 220 that serves as a buried drain (BD) or a buried source (BS). In the preferred embodiment of the present invention, the ion implantation process 212 uses an As ion beam with an energy of about 50KeV and a dosage of about 1E15 cm⁻². Optionally, a rapid thermal processing (RTP) is thereafter used to activate the doped region 220.

As shown in FIG. 7, a high-density plasma CVD (HDPCVD) process is thereafter performed to deposit a 2000 to 3000 angstroms thick HDP oxide layer 240 The HDP oxide layer 240 covers the channel regions 113 and the bit line regions 115 of the active area 110, wherein the top surface of the HDP oxide layer 240 within the bit line region 115 is above the top surface of the PL1 layer 180 and below the top surface of the sacrificial layer 200.

As shown in FIG. 8, an isotropic dry etching process is performed to etch away a portion of the HDP oxide layer 240 until the sacrificial layer 200 is exposed. The isotropic dry etching process is performed in a plasma environment using an etching gas selected from the group consisting of CF₄, CHF₃, C₂F₆, and C₃F₈. The isotropic dry etching process may be carried out in a plasma environment using an etching gas selected from the group consisting of CF₄, CHF₃, C₂ F₆, and C₃ F₈, in combination with oxygen. Notably, it is not preferred to use a CF₄/H₂, CHF_{3 /H}₂, C₂ F₆/H₂, or C₃ F₈/H₂ plasma system, since the hydrogen will react with F atoms in a plasma environment to produce an undesirable HF gas, that might cause acid penetration and random bit failures of flash memories.

In the preferred embodiment, the removed thickness of the HDP oxide layer 240 is about 450 to 750 angstroms, preferably about 600 angstroms. At this point, the original HDP oxide layer 240 is divided into two discontinuous parts: a first HDP oxide layer 240a and a second HDP oxide layer 240b, wherein the first HDP oxide layer 240a is on the sacrificial layer 200 and is removed in the subsequent processes, while the second HDP oxide layer 240b is located adjacent to the gate structures 210.

As shown in FIG. 9, the sacrificial layer 200 is then removed by using a known method in the art, such as a heated phosphoric acid solution. At the same time, the first HDP oxide layer 240a is also removed. A protrusion structure 252 of the second HDP oxide layer 240b is created near the PL1 layer 180 after the removal of the sacrificial layer 200 and the first HDP oxide layer 240a. The protrusion structure 252 can improve the GCR with a gain of about 60% to 75%. Increased coupling ratio can be very beneficial in reducing the required operation voltage of flash memory cell. As shown in FIG. 10, a floating gate 280 is completed by forming a polysilicon layer 260 over the PL1 layer 180. The polysilicon layer 260 is formed by a conventional CVD method, lithographic process and dry etching process.

Finally, as shown in FIG. 11, a dielectric layer 290 is formed on the surface of the floating gate 280 and a polysilicon layer 300 is then formed serving as a control gate of the stacked-gate flash memory cell. Typically, the dielectric layer 290 is an ONO structure that comprises a bottom oxide layer, a nitride layer positioned on the bottom oxide layer and a top oxide layer positioned on the nitride layer. The ONO dielectric layer 290 is formed by ONO processes known in the art.

In comparison with the prior art method, the features of the present invention include: 1) the thermally formed BD/BS oxide layer is replaced with an HDP oxide layer 240b in the present invention, an additional thermal process is thus omitted; 2) the thickness of the HDP oxide layer 240b is well controlled since it is formed by a CVD method; 3) a greatly improved GCR results from the special protrusion structure 252 of the HDP oxide layer 240b; 4) reduced random bit failures caused by acid penetration due to the use of a isotropic dry etching process when etching the HDP oxide layer 240.

Those skilled in the art will readily observe that numerous modification and alterations of the advice may be made while retaining the teachings of the invention. Accordingly, the above disclosure should be construed as limited only by the metes and bounds of the appended claims.

What is claimed is:

1. A method of fabricating a flash memory cell, the method comprising:
providing a substrate, that comprises a channel region and a bit line region in its surface;
forming a stacked layer on the substrate in the channel region, wherein the stacked layer comprises a polysilicon layer and a sacrificial layer formed on the polysilicon layer;
depositing a dielectric layer to cover the channel region and the bit line region, the top surface of the dielectric layer on the surface of the substrate within the bit line region being above the top surface of the polysilicon layer and below the top surface of the sacrificial layer;
isotropically etching away a predetermined thickness of the dielectric layer to expose a portion of the sacrificial layer, and, at the same time, dividing the dielectric layer into a first portion dielectric layer positioned on the sacrificial layer and a second portion dielectric layer that is not connected with the first portion dielectric layer; and
removing the sacrificial layer and the first portion dielectric layer.

2. The method of claim 1 wherein the dielectric layer is an HDP (high density plasma, HDP) oxide layer.

3. The method of claim 1 wherein the substrate further comprises a doped region adjacent to the polysilicon layer in the bit line region, the doped region serves as a buried source (BS) or a buried drain (BD).

4. The method of claim 1 wherein the sacrificial layer comprises silicon nitride.

5. The method of claim 1 wherein the second portion dielectric layer has a protrusion structure near the polysilicon layer that is able to increase GCR (gate coupling ratio) of the flash memory.

6. The method of claim 1 wherein the sacrificial layer is removed by using wet etching.

7. The method of claim 1 wherein the predetermined thickness ranges between 450 and 750 angstroms.

8. The method of claim 1 wherein the predetermined thickness is about 600 angstroms.

9. A method for eliminating HF acid corrosion during a flash memory fabrication process and reducing random bit failures of the flash memory, the method comprising:
providing a substrate having a channel region and a bit line region thereon;
forming a stacked layer on the substrate in the channel region, wherein the stacked layer comprises a first polysilicon layer and a sacrificial layer formed on the first polysilicon layer;
depositing a dielectric layer to cover the channel region and the bit line region;
isotropically etching away a predetermined thickness of the dielectric layer to expose a portion of the sacrificial layer, and, at the same time, dividing the dielectric layer into a first portion dielectric layer positioned on the sacrificial layer and a second portion dielectric layer that is not connected with the first portion dielectric layer;
removing the sacrificial layer;
depositing a second polysilicon layer over the first polysilicon layer such that the first and second polysilicon layers constitute a floating gate for the flash memory;
forming an ONO film over the floating gate; and
forming a third polysilicon layer over the ONO film.

10. The method of claim 9 wherein the top surface of the dielectric layer on the substrate within the bit line region is above top surface of the polysilicon layer and below top surface of the sacrificial layer.

11. The method of claim 9 wherein the dielectric layer is an HDP(high density plasma, HDP) oxide layer.

12. The method of claim 9 wherein the substrate further comprises a doped region adjacent to the polysilicon layer in the bit line region, the doped region serves as a buried source (BS) or a buried drain (BD).

13. The method of claim 9 wherein the sacrificial layer is composed of silicon nitride.

14. The method of claim 9 wherein the second portion dielectric layer has a protrusion structure near the first polysilicon layer that is able to increase GCR (gate coupling ratio) of the flash memory.

15. The method of claim 9 wherein the sacrificial layer is removed by using wet etching.

16. The method of claim 15 wherein the sacrificial layer is removed by using hot phosphoric acid.

17. The method of claim 9 wherein the predetermined thickness ranges between 450 and 750 angstroms.

18. The method of claim 17 wherein the predetermined thickness is about 600 angstroms.
